(19) United States
(12) Patent Application Publication
(10) Pub. No.: US 2008/0017046 A1
(43) Pub. Date: Jan. 24, 2008

(54) Adjusting Device With An At Least Two-Dimensional Sensor Area

(75) Inventors: Johann Huber, Inzell (DE); Wolfgang Schnell, Trostberg (DE); Chritian Unterreiner, Ainring (DE)

Correspondence Address: BSH HOME APPLIANCES CORPORATION;INTELLECTUAL PROPERTY DEPARTMENT, 100 BOSCH BOULEVARD, NEW BERN, NC, 28562, US

(73) Assignee: BSH Bosch und Siemens Haugerate GmbH, MUNICH (DE)

(21) Appl. No.: 11/587,408

(22) PCT Filed: Apr. 26, 2005
(86) PCT No.: PCT/EP05/51861

§ 371 Date: Oct. 23, 2006

(30) Foreign Application Priority Data
Apr. 28, 2004 (DE) 10 2004 020 824.7

(51) Int. Cl. H03K 17/96; A47J 36/00; F24C 7/08

(52) U.S. Cl. 99/325; 200/600

(57) ABSTRACT

An adjusting device for a domestic appliance, in particular, a cooking appliance, has at least one at least two-dimensional sensor area for setting at least one set point. The adjusting device includes an arithmetic unit operable to take into account at least one characteristic, depending on a user position, when setting the set point.

The invention relates in particular to an adjusting device with an at least two-dimensional sensor area according to the preamble of claim 1.

EP 1 273 851 A2 discloses an adjusting device for cooking appliances comprising a touch-sensitive two-dimensional sensor area formed by an adjusting strip. A set point is adjusted depending on a contact position on the adjusting strip whilst switching over between different modes can be achieved by pre-determined contact times.

The object of the invention in particular is to provide a generic adjusting device with increased user friendliness. The object is achieved in each case by the features of the independent claims whilst advantageous embodiments and further developments of the invention can be deduced from the dependent claims.

The invention relates to an adjusting device for a domestic appliance, in particular for a cooking appliance, comprising at least one at least two-dimensional sensor area for setting at least one set point.

It is proposed that the adjusting device comprises a processing unit which is provided to take into account at least one characteristic which deviates from a user position when setting the set point. In this case, the sensed characteristic which deviates from the user position can be taken into account additionally or alternatively to the user position. A setting based on a high information content and therefore particularly user friendly can advantageously be achieved. In addition, as a result of the high information content, the space required is reduced and at the same time, both large and small step jumps can be simply achieved. In particular, power, temperature, pressure, humidity, circulation intensity, luminous intensity etc. can be considered as set points. In this context, an at least two-dimensional sensor area should be understood in particular as an adjusting means which differs from a pure adjusting button, a pure adjusting wheel or a pure rotary switch, wherein in particular its surface extension pointing substantially towards the user is provided for effective adjustment and in particular by means of sensor part areas arranged adjacent to one another in relation to a surface. In addition, “during the adjustment” should be understood to mean that the characteristic is taken into account in particular immediately in time when varying the set quantity.

An adjusting device for a domestic appliance, in particular for a cooking appliance, is further proposed, comprising at least one at least two-dimensional sensor area for setting at least one set point, which comprises a processing unit provided to take into account at least one characteristic which deviates from a user residence time during a switchover. The characteristic which deviates from a user residence time can be taken into account additionally or alternatively to the user residence time. A switchover based on a high information content and therefore particularly user-friendly can again advantageously be achieved and the space required can be reduced.

The characteristic or quantities for determining the characteristic are preferably sensed with a sensor unit of the adjusting device but they can also be sensed by an external sensor unit in relation to the adjusting device and then fed to the adjusting device by means of a data line, such as via a CAN bus, for example (CAN: Controller Area Network), thus saving additional sensors, assembly effort and costs.

If the characteristic is at least dependent on one duration with regard to the setting, additional information which can be used flexibly for the setting can be obtained by means of a simple design and cost efficiently.

It is particularly advantageous if the characteristic is at least dependent on a dynamic quantity and in particular is at least dependent on a user movement speed whereby a very easily remembered and at least largely self-explanatory intuitive setting and also switchover can be simply achieved and in particular, if larger setting jumps and/or switchover jumps can be achieved with increasing user movement speed, for example, by omitting at least intermediate steps. The characteristic dependent on the user movement speed and/or quantities to determine the same can advantageously be determined by recording a time duration. In principle, however, these can also be determined by other quantities, such as for example by the magnitude of the voltage deflection of an inductive circuit etc. which is dependent on a user movement speed.

Additionally or alternatively to a characteristic dependent at least on a user movement speed, a recorded duration can advantageously be used to make a setting dependent on a user residence time. The setting can be made with continuous setting jumps and/or with setting jumps which vary with the user residence time. Increasingly larger setting jumps can preferably be achieved with increasing user residence time.

In a further embodiment of the invention, it is proposed that the characteristic is at least dependent on a user contact surface. A setting and/or switchover can be achieved advantageously simply depending on how many fingers the user uses for the actuation. For example, increasingly larger setting jumps and/or switchover jumps can be achieved with increasing number of fingers used and/or the number of the fingers which the user uses itself results in a certain switching, for example, since a first hot plate can be selected by using one finger and a power delivered by the first hot plate can be set by moving the finger and a second hot plate can be selected by using two fingers and a power delivered by the second hot plate can be set by a movement of the fingers, etc. Furthermore, additional functions and/or operating modes which appear logical to the person skilled in the art can be allocated to using several fingers, such as, for example, automatic switch-on of a browning zone. Instead of a contact surface changed by using a different number of fingers, a contact surface which varies as a result of a contact pressure of a single and/or also several fingers can be detected by a sensor unit and taken into account by the processing unit. However, a user contact pressure can also advantageously be detected by means of a pressure sensor and used for setting and/or switchover, for example, whereby larger setting jumps, switchover jumps and/or directly additional functions such as switching on a browning zone etc. are achieved with increasing user contact pressure.

In a further embodiment of the invention it is proposed that the characteristic is at least dependent on a user-individual quantity. The setting and/or switchover can thereby be adapted quite individually to a specific user. In addition, incorrect settings and/or switchovers caused by individual circumstances can be avoided, for example, if one characteristic is at least dependent on a user contact surface, any influence of different hand sizes of different users can be eliminated so that a corresponding actuation with one and/or with several fingers of different users with different hand sizes nevertheless leads to the same setting result and/or switchover result. Furthermore, the setting and/or switchover can be at least partly blocked with a characteristic which is at least dependent on a user-individual quantity, so that an increased standard of safety can be achieved. For example, different permissions can be granted to children of different ages, so that all electrical hot plates and the baking oven are enabled for a fourteen year old child, for example, but no gas hot plates, and only a single electrical hot plate and this only at a certain power stage and possibly with additionally allocated safety functions, for example, an automatic switch-off after a certain time interval etc. is enabled for a ten-year old child. The characteristic or quantities for determining the same can be sensed by means of a finger pressure scanner, a retina scanner etc.

If the characteristic is at least dependent on a direction of user movement, further convenient setting possibilities and/or switchover possibilities can be achieved. In this case, a direction of user movement can be detected and evaluated by means of a sensor unit only with respect to one dimension or advantageously with respect to two dimensions or with respect to three dimensions. If the direction of movement is detected with respect to two dimensions, a flat sensor field can be provided, for example, by which means characteristics can be sensed for any directions of movement of a user on the sensor field. The flat sensor field can have various shapes which appear appropriate to the person skilled in the art, for example, this can be embodied as round, oval, polygonal etc. If the direction of movement is to be detected with respect to three dimensions, a sensor space can be provided, for example which is monitored by means of at least two cameras in a so-called transmitted-light method. In this case, shadow casting opposite to a light source is recorded at least at two walls and is evaluated. Instead of a corresponding non-contact sensing however, it is also feasible to provide, for example, a flat sensor field which can be recessed to detect a direction of user movement with respect to three dimensions.

If the at least two-dimensional sensor region is embodied as touch-sensitive, simple, cost-effective sensors can be used. However, if the adjusting device has a sensor unit provided for non-contact actuation, the flexibility of the adjusting device with regard to its design and adaptation to special requirements can be further increased and susceptibility to contamination can be further reduced, which can lead to particularly advantageous effects in the case of cooking appliances. In this context, the non-contact actuation can relate to pure activation of the adjusting device by means of a simple motion sensor or a setting and/or switchover by sensing a direction of movement with respect to one, two or even with respect to three dimensions, for example using the aforesaid transmitted-light method wherein one or more shadows cast by one or more light sources on one or more opposite walls are detected by means of one or more cameras. In addition to said transmitted-light method, however, other sensing methods which appear appropriate to the person skilled in the art are also feasible for non-contact actuations, such as for example by means of a sensing method based on infrared technology.

The adjusting device can be connected to a memory unit already provided for another function unit, which can be used to store a parameter relevant for the setting and/or switchover, whereby additional components, assembly effort and costs can be saved, or said adjusting device can advantageously be fitted with a memory unit itself, whereby the memory unit can advantageously be designed for the requirements of the adjusting device. Furthermore, the adjusting device can be manufactured, programmed and checked for its functioning as an at least largely independent unit per se. In addition to the data required for the setting and/or switchover itself, other data which seem appropriate to the person skilled in the art can also be stored in the memory unit, for example, data for an automatic cooker etc.

In addition, an adjusting device is proposed for a domestic appliance, in particular for a cooking appliance, comprising at least one at least two-dimensional sensor area for setting at least one set point, which, in addition to the at least two-dimensional sensor area, comprises at least one extreme value adjusting area for setting an extreme value. A functional unit can thus be set directly to an extreme value without intermediate steps, for example, to a maximum power output or to a minimum power output, whereby comfort can be further increased.

In addition, an adjusting device is proposed for a domestic appliance, in particular for a cooking appliance, comprising at least one at least two-dimensional sensor area for setting at least one set point, which comprises a processing unit which is provided to take into account at least one characteristic which deviates from a user starting position during a re-adjustment. A dependence of the re-adjustment on a user starting position when starting the re-adjustment can be at least reduced or in particular, completely avoided if the processing unit is provided to exclude the user starting position with regard to its influence on the re-adjustment.

In a further embodiment of the invention, it is proposed that the adjusting device comprises a processing unit which is provided to initiate a switchover in the event of at least one repeated action of the user, whereby further switching functions can be simply integrated. In this context, switchover functions can be implemented, for example, by repeated tapping, repeated stroking etc.

If the adjusting device has a voice response unit by which means information relating to the setting and/or switchover can be imparted to the user audibly or by speech, the comfort of the adjusting device can be further enhanced. Furthermore, increased comfort can be achieved if the adjusting device comprises an output unit formed by a screen unit which is preferably provided to reproduce colour pictures. In this context, a screen unit should be understood in particular as a unit which can reproduce pictures at least largely without specific form specifications.

The adjusting device according to the invention is suitable for various areas of application which seem appropriate to the person skilled in the art, but particularly for domestic appliances and in particular for cooking appliances, such as baking ovens, hobs, microwave cookers etc. in which advantageous cleaning conditions and therefore the conditions for particularly hygienic operation can be created by means of a corresponding adjusting device. Moreover, particularly intuitive operation can be ensured.

Further advantages are obtained from the following description of the drawings. The drawings show exemplary embodiments of the invention. The drawings, the description and the claims contain numerous features in combination. The person skilled in the art will appropriately also consider the features individually and combine them to form appropriate further combinations.

In the figures:

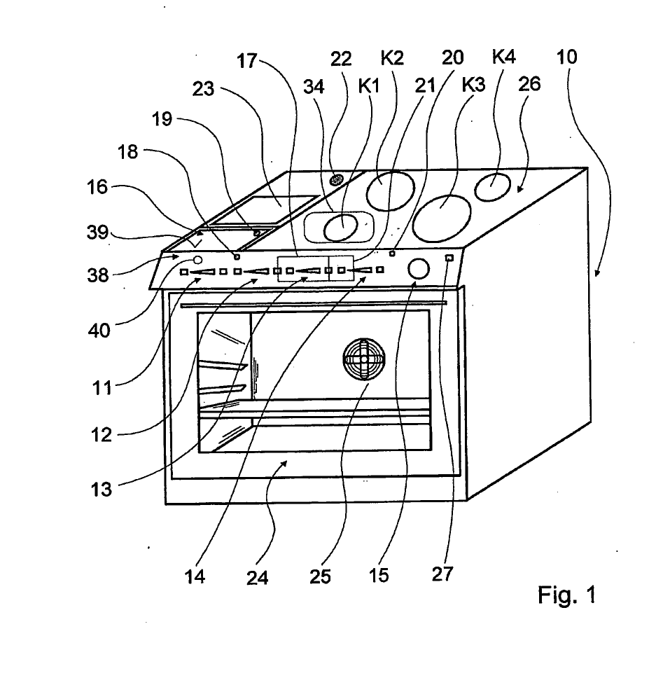

FIG. 1 is a baking oven with a cooking hob obliquely from the side,

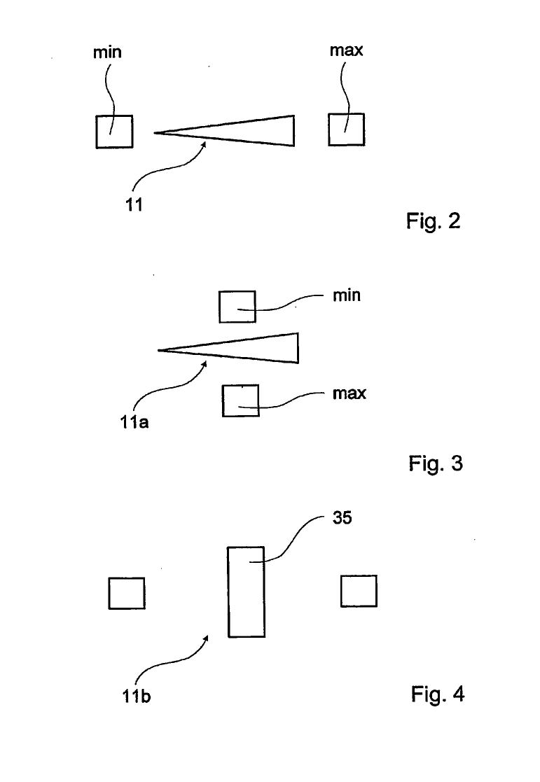

FIG. 2 is an enlarged section of a two-dimensional sensor area from FIG. 1,

FIG. 3 is a first alternative two-dimensional sensor area,

FIG. 4 is a second alternative two-dimensional sensor area,

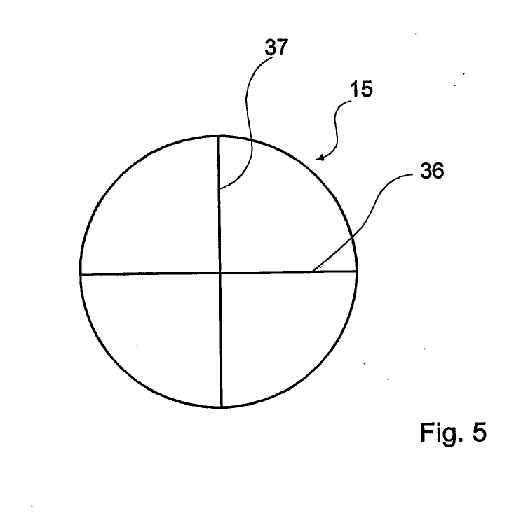

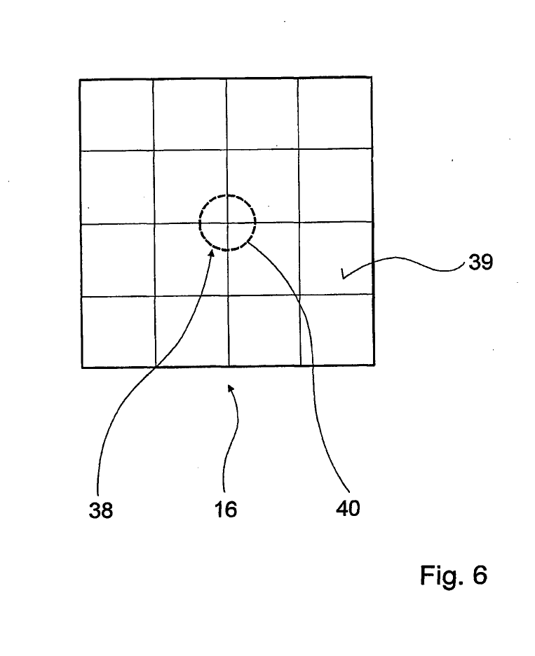

FIG. 5 is an enlarged section of a further two-dimensional sensor area from FIG. 1,

FIG. 6 is a plan view of a three-dimensional sensor area from FIG. 1 and

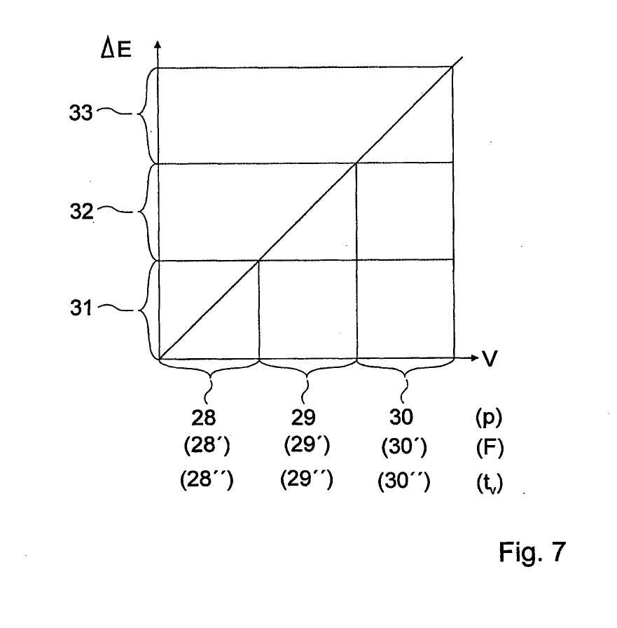

FIG. 7 is a diagram of setting jumps in particular by means of a user movement speed.

FIG. 1 shows a cooker 10 comprising a baking oven 24 with a muffle 25 and a cooking hob 26 with four hot plates K1, K2, K3, K4. The cooker 10 has an adjusting device according to the invention which comprises for each hot plate K1, K2, K3, K4 a two-dimensional sensor area 11, 12, 13, 14, a two-dimensional sensor area 15 for setting a cooking time and a three-dimensional sensor area 16 for the baking oven 24. In each case, in particular, a power output by the hot plates K1, K2, K3, K4 can be set by means of the sensor areas 11, 12, 13, 14 arranged on an upwardly sloping front side. A switchover between various baking functions and a setting of a cooking power can be made by means of the sensor area 16 located in the edge zone of top side of the cooker 10.

If a user is positioned directly in front of the cooker 10, this is either detected by means of two movement sensors arranged on the front side and/or by means of one movement sensor arranged on the top side 18, 19, 20, and the adjusting device is shifted into a readiness position by means of a processing unit 17. In this readiness position the front side is illuminated in the region of the sensor areas 11, 12, 13, 14, 15 and the top side is illuminated in the region of the sensor area 16. If the user then wishes to make a setting by means of the adjusting device, he must first identify this by pressing his index finger on a finger pressure scanner 27 on the front side. The detected data are then compared with data sets stored in a memory unit 21 of the adjusting device on a first commissioning. If the cooker 10 is blocked for the user, for example, if the user is an underage child, said user cannot make any setting, any switchover or selection via the adjusting device.

If the cooker 10 is enabled for the user, he can set the heating power delivered by the hot plates K1, K2, K3, K4 by means of the sensor areas 11, 12, 13, 14. The function of the sensor area 11 will be explained hereinafter, said area having the same structure as the sensor areas 12, 13, 14 for which reference may be made to the description for the sensor area 11 apart from switching-in a browning zone.

The sensor area 11 is characterised by a horizontally aligned elongated wedge and is embodied as touch-sensitive. A piezotechnical sensor unit is located under the elongated wedge. Instead of a piezotechnical sensor unit, however, other sensor units are also feasible, such as, for example capacitive, inductive, optical and/or thermal sensor units etc.

If the user moves a finger placed on the sensor area 11 from left to right, a higher power stage is set with increasing distance. In this case, the processing unit 17 is provided to select setting jumps ΔE which occur during setting, dependent on a user movement speed v. A present power span of the hot plate K1 is divided into nine stages. If the user movement speed v lies in a lower speed range 28, the power is increased by respectively one stage in each case in a first setting jump range 31 during a movement of the user from left to right and is reduced by respectively one stage during a movement from right to left (FIG. 7). If the user movement speed v lies in a second speed range 29, the power is increased in a second setting jump range 32 by respectively two stages during a movement of the user from left to right and is reduced by respectively two stages during a movement from right to left. If the user movement speed v lies in a third speed range 30, the power is increased in a third setting jump range 33 by respectively three stages during a movement of the user from left to right and is reduced by respectively three stages during a movement from right to left.

A corresponding dependence further exists between a user contact pressure p and a user contact surface F, i.e. the first setting jump area 31 is allocated to the first pressure area 28′, the second setting jump area 32 is allocated to a second higher pressure area 29′, and the third setting jump area 33 is allocated to a third highest pressure area 30′ and the first setting jump area 31 is allocated to the first surface area 28″, the second setting jump area 32 is allocated to a second higher surface area 29″, and the third setting jump area 33 is allocated to a third highest surface area 30″. In this context, the first surface area 28″ is allocated operation with one finger, the second surface area 29″ is allocated operation with two fingers and the third surface area 30″ is allocated operation with three fingers. In order to avoid a different setting being achieved by a user with a large hand area as compared with a user with a small hand area, the area sizes are allocated to different users. During a first commissioning, the respectively different area sizes are detected per user. When the user identifies himself during a subsequent operation, the data set allocated to this user is used, since this contains the size of the contact surface F of one, two and three fingers for this special user.

If the maximum power stage 9 is set and the user executes a repeated action by again moving one, two or three fingers from left to right on the sensor area 11, this triggers a parboiling surge.

Furthermore, a switchover or additional switching and switching off a browning zone 34 can be achieved via the sensor area 11 by the user staying for more than five seconds on the sensor area 11 with a user contact surface F formed by one of three fingers. The switchover is thus dependent on a user contact surface F in addition to a user residence time.

The processing unit 17 is provided to exclude the user starting position with regard to its influence on a re-adjustment, i.e. if a heating power is set and this is to be changed during a re-adjustment, the re-adjustment is independent of the new contact position of the user. Rather, a re-adjustment only takes place depending on a movement to the left or right following the contact of one or more fingers.

In addition, two extreme value adjusting areas min, max for setting extreme values are also allocated to the sensor area 11. By touching the extreme value adjusting area min, the minimum power stage 1 can be set immediately and by touching the extreme value adjusting area max, the maximum power stage 9 can be set immediately.

The extreme value adjusting area min is arranged in a direction of movement from a low power stage to a high power stage from left to right in front of the sensor area 11 and the extreme value adjusting area max is arranged after the sensor area 11. The extreme value adjusting areas min, max could, however, also be arranged at other positions which appear appropriate to the person skilled in the art, for example above or below a sensor area 11a corresponding to the sensor area 11 (FIG. 3).

The power stage of the respective hot plate K1, K2, K3, K4 which has been set is output audibly a loudspeaker of a voice response unit 22 and visually via a flat screen unit 23, both located in the edge zone of the top side and covered with a protective glass plate. The flat screen unit 23 is provided for reproducing colour pictures. The processing unit 17 can additionally be connected to the Internet so that, in addition to information on the selected cooking modes and set points etc. internet pages can be displayed and television programs can also be output.

As an alternative to the sensor area 11, a sensor area 11b with an integrated seven-segment display unit 35 can also be provided, as shown in FIG. 4. In principle, however, it would also be feasible to position a seven-segment display unit next to a sensor area, for example.

A sensor unit 38 for non-contact actuation is allocated to the sensor area 16, comprising a camera 40 located underneath a glass plate 39 (FIGS. 1 and 6). The sensor unit 38 also comprises a light source not shown in detail in an extraction hood likewise not shown in detail which is directed onto the sensor area 16 from above.

To activate the sensor area 16 the user passes his entire hand area with stretched and closed fingers over the camera 40 in the sensor area 16 and stays there for at least three seconds. The camera 40 detects a shadow cast by the hand area of the user and after three seconds has elapsed, the processing unit 17 activates the sensor 16 for setting and switchover.

After activating the sensor area 16, the user can select different operating modes or switch between different operating modes with predetermined signs and therefore different shadows cast which are detected by the camera 40. If the user bends all his fingers apart from the index finger in the sensor area 16, a first operating mode is thereby selected and this is the operating mode characterised by circulating-air operation. If the user bends all his fingers except the index finger and the middle finger, and spreads the stretched fingers, a second operating mode is selected and this is the operating mode characterised by top heat. If the user bends the thumb and index finger and spreads the extended middle finger, ring finger and little finger, a third operating mode is selected and this is the operating mode characterised by bottom heat. If the user only bends the thumb and spreads the remaining fingers, a fourth operating mode is selected and this is the operating mode characterised by grill operation. If the user stretches all his fingers in the sensor area 16 and spreads these, a fifth operating mode is selected and this is the operating mode characterised by bottom heat, overheat and circulating air. If a further sign is given by the user within five seconds of selecting an operating mode, a further operating mode is activated in combination with the first selected operating mode. In order to deactivate all the operating modes, the user bends all his fingers or forms his hand into a fist in the sensor area 16. In principle, it is also feasible for the corresponding signs to the changed into individual signs by a user.

Once an operating mode is selected, the user can set the heating power in a non-contact manner by means of the sensor area 16. If the user moves his outstretched index finger from left to right, a higher power stage is set with increasing distance and this is achieved indirectly by the user setting a target temperature in the baking oven muffle 25. In this case, the processing unit 17 is provided to select setting jumps which occur during setting dependent on a user movement speed v. If the user movement speed lies in a lower speed range and the user moves his hand from left to right with the fingers bent apart from the index finger, the target temperature in the baking oven muffle 25 is increased by five-degree jumps in each case. If the user moves his hand accordingly from right to left, the target temperature is reduced in five-degree jumps. If the user movement speed lies in a second higher speed range and the user moves his hand from left to right with the fingers bent apart from the index finger, the target temperature in the baking oven muffle 25 is increased by ten-degree jumps in each case. If the user moves his hand accordingly from right to left, the target temperature is reduced in ten-degree jumps. If the user movement speed lies in a third highest speed range and the user moves his hand from left to right with the fingers bent apart from the index finger, the target temperature in the baking oven muffle 25 is increased by twenty-degree jumps in each case. If the user moves his hand accordingly from right to left, the target temperature is reduced in twenty-degree jumps.

If the user stretches out the middle finger in addition to the index finger when setting the heating power, the degree jumps are doubled compared to a setting with only the index finger outstretched.

The sensor area 15 is characterised by a circular surface. A contact-sensitive piezotechnical sensor unit is located underneath the circular surface. Instead of the piezotechnical sensor unit, other sensor units are also feasible however, such as capacitive, inductive, optical and/or thermal sensor units.

If one of the hot plates K1, K2, K3, K4 or the baking oven 24 is activated, a cooking time in which the corresponding hot plate K1, K2, K3, K4 or the baking oven 24 is to be operated at the set heating power can be set immediately after its activation by means of the sensor area 15. If a user moves a finger placed on the sensor area 15 from left to right, a longer cooking time is set with increasing distance. In this case, the processing unit 17 is provided to select setting jumps which occur during the setting dependent on a direction of user movement. The flatter the user moves his fingers in relation to a horizontal axis 36, the larger the setting jumps which are made. Hence, a coarse setting with large setting jumps can be achieved with a horizontal movement over the sensor area 15 and a fine setting can be achieved with a movement close to a substantially vertical axis 37. In addition, a cooking time can be set by the user leaving his finger on the sensor area 15. If the user stays in the region to the right of the axis 37, the cooking time increases whilst if the user stays in the region to the left of the 37, the cooking time decreases.

TABLE 1

| | |
|---|---|
| 10 | Household appliance |
| 11 | Sensor area |
| 12 | Sensor area |
| 13 | Sensor area |
| 14 | Sensor area |
| 15 | Sensor area |
| 16 | Sensor area |
| 17 | Processing unit |
| 18 | Sensor unit |
| 19 | Sensor unit |
| 20 | Sensor unit |
| 21 | Memory unit |
| 22 | Voice response unit |
| 23 | Screen unit |
| 24 | Baking oven |
| 25 | Baking oven muffle |
| 26 | Cooking hob |
| 27 | Finger pressure scanner |
| 28 | Speed area |
| 28′ | Pressure area |
| 28″ | Surface area |
| 29 | Speed area |
| 29′ | Pressure area |
| 29″ | Surface area |
| 30 | Speed area |
| 30′ | Pressure area |
| 30″ | Surface area |
| 31 | Setting jump range |
| 32 | Setting jump range |
| 33 | Setting jump range |
| 34 | Browning zone |
| 35 | Seven-segment display unit |
| 36 | Axis |
| 37 | Axis |
| 38 | Sensor unit |
| 39 | Glass plate |
| 40 | Camera |
| v | User movement speed |
| F | User contact surface |
| p | User contact pressure |
| min | Extreme value adjusting |
| | range |
| max | Extreme value adjusting |
| | range |
| K1 | Hot plate |
| K2 | Hot plate |
| K3 | Hot plate |
| K4 | Hot plate |
| ΔE | Setting jump |

1-21. (canceled)

22. An adjusting device for a domestic appliance, in particular for a cooking appliance, the adjusting device comprising:
at least one sensor area configured as a selected one of a two-dimensional sensor area and a three-dimensional sensor area, the sensor area for setting at least one set point and having a processing unit operable to take into account at least one characteristic that deviates from a user position when setting the set point.

23. The adjusting device according to claim 22, wherein the processing unit is operable to take into account at least one characteristic which deviates from a user residence time during a switchover.

24. The adjusting device according to claim 22, wherein the characteristic is at least dependent on a duration.

25. The adjusting device according to claim 22, wherein the characteristic is at least dependent on a dynamic quantity.

26. The adjusting device according to claim 22, wherein the characteristic is at least dependent on a user movement speed.

27. The adjusting device according to claim 22, wherein the characteristic is at least dependent on a user contact surface.

28. The adjusting device according to claim 22, wherein the characteristic is at least dependent on a user contact pressure.

29. The adjusting device according to claim 22, wherein the characteristic is at least dependent on a user-individual quantity.

30. The adjusting device according to claim 22, wherein the characteristic is at least dependent on a direction of user movement.

31. The adjusting device according to claim 30, wherein the characteristic is dependent on at least two movement dimensions.

32. The adjusting device according to claim 22, wherein the sensor area is embodied as touch-sensitive.

33. An adjusting device for a domestic appliance, in particular for a cooking appliance, the adjusting device comprising:
at least one sensor area configured as a selected one of a two-dimensional sensor area and a three-dimensional sensor area, the sensor area for setting at least one set point and having a sensor unit operable via non-contact actuation.

34. The adjusting device according to claim 22 and further comprising a memory unit for storing at least one parameter.

35. An adjusting device for a domestic appliance, in particular for a cooking appliance, the adjusting device comprising:
at least one sensor area configured as a selected one of a two-dimensional sensor area and a three-dimensional sensor area, the sensor area for setting at least one set point; and
at least one extreme value adjusting area (min, max) for setting an extreme value.

36. An adjusting device for a domestic appliance, in particular for a cooking appliance, the adjusting device comprising:
at least one sensor area configured as a selected one of a two-dimensional sensor area and a three-dimensional sensor area, the sensor area for setting at least one set point and having a processing unit operable to take into account at least one characteristic that deviates from a user starting position during a re-adjustment.

37. The adjusting device according to claim 36, wherein the processing unit is operable to exclude the user starting position with regard to its influence on the re-adjustment.

38. The adjusting unit according to claim 22, wherein the processing unit is operable to initiate a switchover during at least one repeated user action.

39. The adjusting unit according to claim 22 and further comprising a voice response unit.

40. The adjusting unit according to claim 22 and further comprising an output unit formed by a screen unit.

41. The adjusting device according to claim 40, wherein the screen unit is operable to reproduce color pictures.

42. A cooking appliance comprising:
an element for generating heat to assist in a cooking operation; and
an adjusting device including at least one sensor area configured as a selected one of a two-dimensional sensor area and a three-dimensional sensor area, the sensor area for setting at least one set point and having a processing unit operable to take into account at least one characteristic that deviates from a user position when setting the set point.
